(19) United States
(12) Patent Application Publication
(10) Pub. No.: US 2024/0231163 A1
(43) Pub. Date: Jul. 11, 2024

(54) ARRAY BASE PLATE AND DISPLAY PANEL

(71) Applicants: Ordos Yuansheng Optoelectronics Co., Ltd., Ordos, Inner Mongolia (CN); BOE Technology Group Co., Ltd., Beijing (CN)

(72) Inventors: Peirong HUO, Beijing (CN); Bo LI, Beijing (CN); Peng LIU, Beijing (CN); Yongqiang ZHANG, Beijing (CN); Jingyi XU, Beijing (CN)

(21) Appl. No.: 17/911,491

(22) PCT Filed: Oct. 25, 2021
(86) PCT No.: PCT/CN2021/126090

§ 371 Date: Sep. 14, 2022

(30) Foreign Application Priority Data
May 20, 2021 (CN) 202110554410.0

(51) Int. Cl. G02F 1/1362; G02F 1/1368; H01L 27/12

(52) U.S. Cl. CPC G02F 1/136209; G02F 1/136286; G02F 1/1368; H01L 27/124

(57) ABSTRACT

The array base plate includes a plurality of sub-pixels that are arranged in an array; each of the sub-pixels includes a light shielding layer, a semiconductor layer, a grid layer, a source-drain layer and a pixel electrode layer that are arranged in layer configuration on the substrate sequentially; the semiconductor layer includes a first contacting part, a first channel part, a doping part, a second channel part and a second contacting part that are sequentially connected; the grid layer includes a first grid electrode and a second grid electrode; the source-drain layer includes a first electrode and a second electrode; and an orthographic projection of the light shielding layer on the substrate at least covers orthographic projections on the substrate of the first channel part, the second channel part and a part of the first contacting part.

### CROSS REFERENCE TO RELEVANT APPLICATIONS

The present application claims the priority of the Chinese patent application filed on May 20, 2021 before the Chinese Patent Office with the application number of 202110554410.0 and the title of “ARRAY BASE PLATE AND DISPLAY PANEL”, which is incorporated herein in its entirety by reference.

### TECHNICAL FIELD

The present application relates to the technical field of displaying and, more particularly, to an array base plate and a display panel.

### BACKGROUND

Liquid-crystal displays are very important in the field of displaying, and are currently extensively applied to products having the function of displaying such as television sets, mobile phones and computers. With the increasingly higher requirements by users, high pixel density (Pixels Per Inch, PPI) products emerge correspondingly. In order to have product qualities of a high definition and low weight and thickness, liquid-crystal displays are required to satisfy the design requirements of a low screen size, a high pixel density and a high brightness of the backlight source. However, the products satisfying those requirements have a very serious illumination leakage current, which results in serious flicker phenomenon, thereby highly reducing the displaying quality.

### SUMMARY

The embodiments of the present application provide an array base plate and a display panel.

The embodiments of the present application employ the following technical solutions:

In an aspect, there is provided an array base plate, wherein the array base plate includes a substrate and a plurality of sub-pixels that are disposed on the substrate and are arranged in an array:

each of the sub-pixels includes a light shielding layer, a semiconductor layer, a grid layer, a source-drain layer and a pixel electrode layer that are arranged in layer configuration on the substrate sequentially:

the semiconductor layer includes a first contacting part, a first channel part, a doping part, a second channel part and a second contacting part that are sequentially connected:

the grid layer includes a first grid electrode and a second grid electrode:

the source-drain layer includes a first electrode and a second electrode:

the pixel electrode layer includes a pixel electrode;

the first electrode is electrically connected to the first contacting part and the pixel electrode, and the second electrode is electrically connected to the second contacting part:

the first channel part and the first grid electrode intersect or overlap in a direction perpendicular to the substrate, and the second channel part and the second grid electrode intersect or overlap in the direction perpendicular to the substrate: and

an orthographic projection of the light shielding layer on the substrate at least covers orthographic projections on the substrate of the first channel part, the second channel part and a part of the first contacting part.

Optionally, the grid layer further includes a grid line:

the first grid electrode is a part of the grid line that intersects or overlaps with the first channel part in the direction perpendicular to the substrate, and the second grid electrode is a part of the grid line that intersects or overlaps with the second channel part in the direction perpendicular to the substrate: and

the grid line extends in a first direction, an orthographic projection of the doping part on the substrate is located on a first side of an orthographic projection of the grid line on the substrate, and orthographic projections of the first contacting part and the second contacting part on the substrate are located on a second side of the orthographic projection of the grid line on the substrate, wherein the first side and the second side are opposite.

Optionally, the light shielding layer extends in the first direction, and the orthographic projection of the grid line on the substrate is located within the orthographic projection of the light shielding layer on the substrate.

Optionally, the light shielding layer includes at least an overlapping part and a first part, the overlapping part extends in the first direction, an orthographic projection of the overlapping part on the substrate coincides with the orthographic projection of the grid line on the substrate, and an orthographic projection of the first part on the substrate is located on the second side of the orthographic projection of the grid line on the substrate:

the first contacting part includes a first contacting sub-part and a first doping sub-part, the first doping sub-part is disposed between the first contacting sub-part and the first channel part, and the first contacting sub-part is electrically connected to the first electrode: and

an orthographic projection of the first doping sub-part on the substrate is located within the orthographic projection of the first part on the substrate: and/or, an orthographic projection of the first contacting sub-part on the substrate is located within the orthographic projection of the first part on the substrate.

Optionally, the orthographic projection of the second contacting part on the substrate and the orthographic projection of the first part on the substrate do not intersect or overlap, and the orthographic projection of the doping part on the substrate and the orthographic projection of the light shielding layer on the substrate do not intersect or overlap.

Optionally, when the orthographic projection of the first contacting sub-part on the substrate is located within the orthographic projection of the first part on the substrate, and the orthographic projection of the first doping sub-part on the substrate and the orthographic projection of the first part on the substrate do not intersect or overlap, the first part and the overlapping part are not connected.

Optionally, the second contacting part includes a second contacting sub-part and a second doping sub-part, the second doping sub-part is disposed between the second contacting sub-part and the second channel part, and the second contacting sub-part is electrically connected to the second electrode: and

at least part of an orthographic projection of the second doping sub-part on the substrate is located within the orthographic projection of the first part on the substrate.

Optionally, an orthographic projection of the second contacting sub-part on the substrate and the orthographic projection of the first part on the substrate do not intersect or overlap.

Optionally, when the orthographic projection of the first doping sub-part on the substrate is located within the orthographic projection of the first part on the substrate, and the orthographic projection of the first contacting sub-part on the substrate and the orthographic projection of the first part on the substrate do not intersect or overlap, the first part extends in the first direction, and is connected to the overlapping part.

Optionally, a length of the second doping sub-part in a second direction is greater than a length of the first doping sub-part in the second direction:

a width of the first part in the second direction is equal to the length of the first doping sub-part in the second direction, wherein the second direction is perpendicular to the first direction; and

the orthographic projection of the doping part on the substrate and the orthographic projection of the light shielding layer on the substrate do not intersect or overlap.

Optionally, the light shielding layer further includes a second part, and an orthographic projection of the second part on the substrate is located on the first side of the orthographic projection of the grid line on the substrate: and

the orthographic projection of the second part on the substrate and the orthographic projection of the doping part on the substrate partially intersect or overlap, and a width of the second part in a second direction is less than a width of the first part in the second direction.

Optionally, when the orthographic projection of the first doping sub-part on the substrate and the orthographic projection of the second doping sub-part on the substrate are located within the orthographic projection of the first part on the substrate, and the orthographic projections on the substrate of the first contacting sub-part, the second contacting sub-part and the doping part do not intersect or overlap with the orthographic projection of the first part on the substrate, the first part includes a first sub-part and a second sub-part, both of the first sub-part and the second sub-part are connected to the overlapping part, the orthographic projection of the first doping sub-part on the substrate is located within an orthographic projection of the first sub-part on the substrate, and the orthographic projection of the second doping sub-part on the substrate is located within an orthographic projection of the second sub-part on the substrate.

Optionally, an orthographic projection of the semiconductor layer on the substrate is located within the orthographic projection of the light shielding layer on the substrate, and a shape of a boundary of the orthographic projection of the light shielding layer on the substrate and a shape of a boundary of the orthographic projection of the semiconductor layer on the substrate are the same.

Optionally, the light shielding layer includes a first light shielding part and a second light shielding part that are not connected, an orthographic projection of the first light shielding part on the substrate at least covers an orthographic projection of the first grid electrode on the substrate and a part of an orthographic projection of the first contacting part on the substrate, and an orthographic projection of the second light shielding part on the substrate at least covers an orthographic projection of the second grid electrode on the substrate and a part of the orthographic projection of the second contacting part on the substrate.

In another aspect, there is provided a display panel, wherein the display panel includes a color-film base plate and the array base plate stated above that face each other: and

the color-film base plate includes a black matrix, and an orthographic projection of the black matrix on the substrate of the array base plate covers the orthographic projection of the light shielding layer of the array base plate on the substrate.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the prior art, the figures that are required to describe the embodiments or the prior art will be briefly introduced below. Apparently, the figures that are described below are merely embodiments of the present application, and a person skilled in the art can obtain other figures according to these figures without paying creative work.

FIG. 1 is an energy level diagram of a semiconductor layer according to an embodiment of the present application:

FIG. 2 is a comparison diagram of the leakage currents of an NMOS transistor and a PMOS transistor before and after illumination according to an embodiment of the present application:

FIG. 3 is a comparison diagram of the leakage currents of different samples in different illumination environments according to an embodiment of the present application:

FIG. 4 is a schematic structural diagram of an array base plate according to an embodiment of the present application:

FIG. 5 is a schematic diagram of a driving process according to an embodiment of the present application:

FIG. 6a is a schematic structural diagram of another array base plate according to an embodiment of the present application:

FIG. 6b is a schematic structural diagram of yet another array base plate according to an embodiment of the present application:

In FIG. 7a. FIG. a1 is a schematic structural diagram of a light shielding layer according to an embodiment of the present application, FIG. a2 is a schematic structural diagram of the formation of a semiconductor layer on the basis of FIG. a1, and FIG. a3 is a schematic structural diagram of the formation of a grid line on the basis of FIG. a2:

In FIG. 7b, FIG. a4 is a schematic structural diagram of another light shielding layer according to an embodiment of the present application, FIG. a5 is a schematic structural diagram of the formation of a semiconductor layer on the basis of FIG. a4, and FIG. a6 is a schematic structural diagram of the formation of a grid line on the basis of FIG. a5:

FIG. 8a is a cross-sectional view along the CD direction in FIG. a3 in FIG. 7a:

FIG. 8b is a cross-sectional view along the CD direction in FIG. a6 in FIG. 7b:

In FIG. 9, FIG. b1 is a schematic structural diagram of a light shielding layer according to an embodiment of the present application, FIG. b2 is a schematic structural diagram of the formation of a semiconductor layer on the basis of FIG. b1, and FIG. b3 is a schematic structural diagram of the formation of a grid line on the basis of FIG. b2:

FIG. 10 is a cross-sectional view along the CD direction in FIG. b3 in FIG. 9;

In FIG. 11. FIG. c1 is a schematic structural diagram of a light shielding layer according to an embodiment of the present application. FIG. c2 is a schematic structural diagram of the formation of a semiconductor layer on the basis of FIG. c1, and FIG. c3 is a schematic structural diagram of the formation of a grid line on the basis of FIG. c2:

FIG. 12 is a cross-sectional view along the CD direction in FIG. c3 in FIG. 11:

In FIG. 13. FIG. d1 is a schematic structural diagram of a light shielding layer according to an embodiment of the present application. FIG. d2 is a schematic structural diagram of the formation of a semiconductor layer on the basis of FIG. d1, and FIG. d3 is a schematic structural diagram of the formation of a grid line on the basis of FIG. d2;

FIG. 14 is a cross-sectional view along the CD direction in FIG. d3 in FIG. 13:

In FIG. 15. FIG. e1 is a schematic structural diagram of a light shielding layer according to an embodiment of the present application. FIG. e2 is a schematic structural diagram of the formation of a semiconductor layer on the basis of FIG. e1, and FIG. e3 is a schematic structural diagram of the formation of a grid line on the basis of FIG. e2:

FIG. 16 is a cross-sectional view along the CD direction in FIG. e3 in FIG. 15:

FIG. 17a1 and FIG. 17a2 are two electron microscope diagrams: and

FIG. 18 is a schematic structural diagram of a display panel according to an embodiment of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first” and “second” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

A liquid-crystal display panel includes an array base plate and a color-film base plate that face each other, and a liquid crystal disposed between the array base plate and the color-film base plate. Because the liquid crystal cannot emit light, in order to realize displaying, the liquid-crystal display panel further includes a backlight source, and the backlight source may be disposed on the side of the array base plate that is further from the color-film base plate. The light rays emitted by the backlight source sequentially pass through the array base plate, the liquid crystal and the color-film base plate, and because the liquid-crystal molecules deflect under the effect of an electric field, the quantity of the passing-through light rays can be changed, thereby realizing the displaying of different frames. The array base plate includes a plurality of sub-pixels that are arranged in an array, and usually the electric fields generated by each of the sub-pixels are controlled by using thin-film transistors, to in turn control the deflection of the liquid crystal.

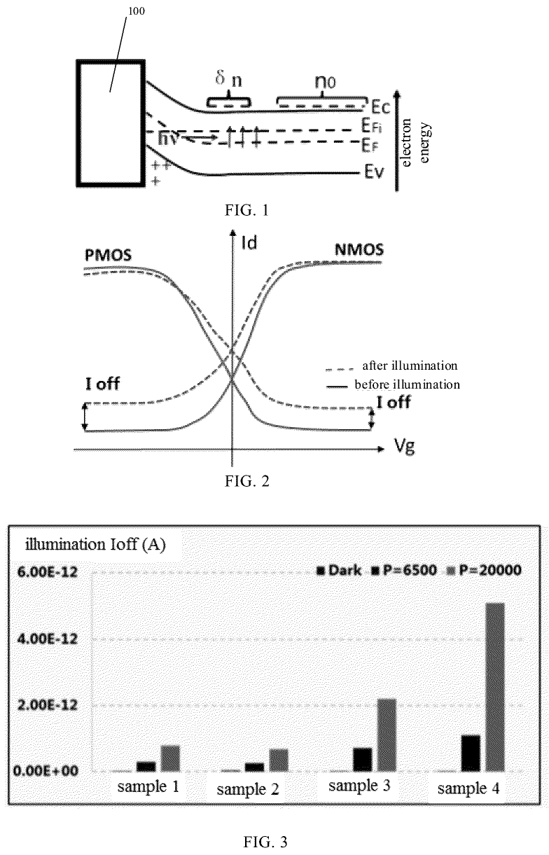

However, the semiconductor layer of a thin-film transistor (TFT) is easily influenced by illumination, to generate a leakage current. By taking an N-type semiconductor as an example for the description, referring to FIG. 1, the fermi energy level E_{Fi} of the N-type semiconductor 100 is higher than the intrinsic fermi energy level E^{F}. Under an external illumination, the charge carrier is mainly from intrinsic excitation, in which case the fermi energy level is close to the intrinsic fermi energy level. At a certain temperature, the semiconductor is irradiated by using a light of the photon energy of hv≥Eg (forbidden band width), in which case the conditions of the equilibrium state are broken, and the semiconductor is in the non-equilibrium state, which is deviated from the equilibrium state. Before the illumination, the electron concentration in the semiconductor is n0, and after the illumination, the electron concentration in the semiconductor in the non-equilibrium state is n=n0+δn, wherein on is the photon-generated carrier. In FIG. 1. Ec represents the bottom of conduction band. i.e., the lowest energy level of the conduction band, and Ev represents the value band edge.

Referring to FIG. 2, in both of an NMOS transistor and a PMOS transistor, the leakage current I_{off} after the illumination is greater than the leakage current I_{off} before the illumination. In FIG. 2, the horizontal coordinate Vg represents the grid voltages of the transistors, and the vertical coordinate Id represents the drain-source currents of the transistors. In addition, the variable that primarily influences the increasing of the leakage current is the illumination, and the illumination intensity is positively correlated with the numerical value of the illumination leakage current. By testing the leakage currents of four TFTs of different specifications in a dark environment (Dark), a 6500 nit-illuminated environment P1 and a 20000 nit-illuminated environment P2, the diagram of the test result shown in FIG. 3 is obtained. It can be obtained from FIG. 3 that, in any one of the samples, with the increasing of the illumination brightness, the leakage current increases accordingly, and if the illumination brightness is higher, the leakage current is higher.

In high-PPI products (for example, 1000 PPI and 1200 PPI), both of the pixel density and the backlight-source brightness are designed very high, whereby the high-PPI products have a very serious illumination leakage current. The illumination leakage current results in flicker problem, which highly reduces the effect of displaying.

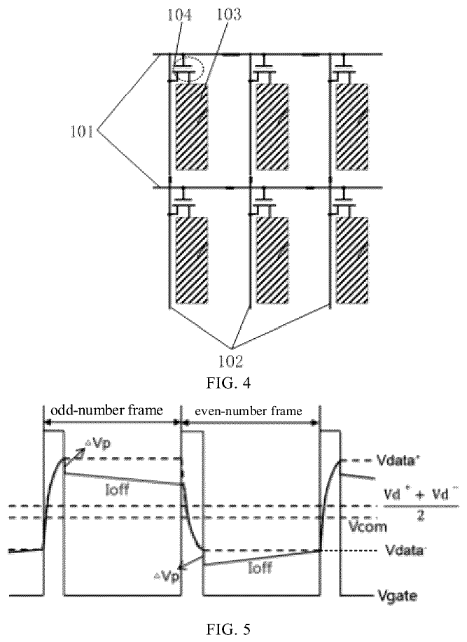

Referring to FIG. 4, the array base plate includes a plurality of grid lines 101 and a plurality of data lines 102, the grid lines 101 are electrically connected to the grid electrodes of the TFTs 104 of each row of the sub-pixels, and the data lines 102 are electrically connected to one electrode of the TFTs 104 of each column of the sub-pixels. In each of the sub-pixels, the other electrode of the TFT 104 is electrically connected to the pixel electrode 103. The principle of the generation of the flicker will be described by taking the driving process of the TFT of one of the sub-pixels as an example. Referring to FIG. 5, in an odd-number frame, the grid is inputted a Vgate signal via the grid line. When the voltage of the Vgate signal is a high level, the TFT is turned on, and the data line outputs a positive-polarity Vdata⁺ signal, to charge the TFT, whereby the voltage of the pixel electrode is changed into Vd⁺. However, because of the existence of the parasitic capacitance, the voltage of the pixel electrode is reduced by ΔVp. Subsequently, the voltage of the Vgate signal is changed into a low level, and the TFT enters the maintaining stage. In an ideal state, before the next time of charging, the voltage of the pixel electrode always maintains the charging voltage. However, if influenced by illumination, the TFT may generate a leakage current, whereby the voltage of the pixel electrode continuously decreases over the maintaining duration.

In the next even-number frame, the voltage of the Vgate signal is a high level, the TFT is turned on the data line outputs a negative-polarity Vdata⁻ signal, and the TFT discharges to complete the reverse charging, whereby the voltage of the pixel electrode is changed into Vd⁻. However, because of the existence of the parasitic capacitance, the voltage of the pixel electrode is reduced by ΔVp. Subsequently, the voltage of the Vgate signal is changed into a low level, and the TFT enters the maintaining stage. In an ideal state, before the next time of charging, the voltage of the pixel electrode always maintains the charging voltage. However, if influenced by illumination, the TFT generates a leakage current, whereby the absolute value of the voltage of the pixel electrode continuously decreases over the maintaining duration. Because of the existence of the leakage current in the maintaining stage, the brightnesses of the sub-pixel in the two consecutive frames have a difference therebetween, whereby human eyes can identify a flicker. If the driving mode of column inversion is employed, in practical usage, obvious shaking-head vertical textures appear, thereby highly reducing the displaying quality.

In addition, in FIG. 5. Vcom refers to the voltage of a common electrode, and the pixel electrode and the common electrode form an electric field, to cause the liquid-crystal molecules to deflect. The Vcom voltage may be (Vd⁺+Vd⁻)/2. However, because of the existence of the parasitic capacitance, the voltage of the pixel electrode is reduced by ΔVp. In order to ensure that the voltage difference of the liquid-crystal molecules is unchanged, the Vcom voltage may be compensated: in other words, the Vcom voltage shown in FIG. 5 may be employed, and the voltage source is less than (Vd⁺+Vd⁻)/2.

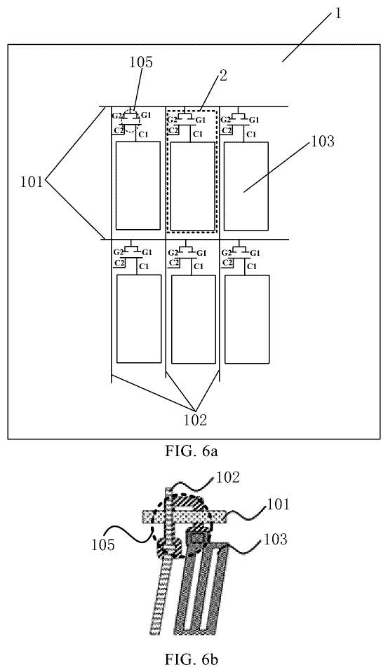

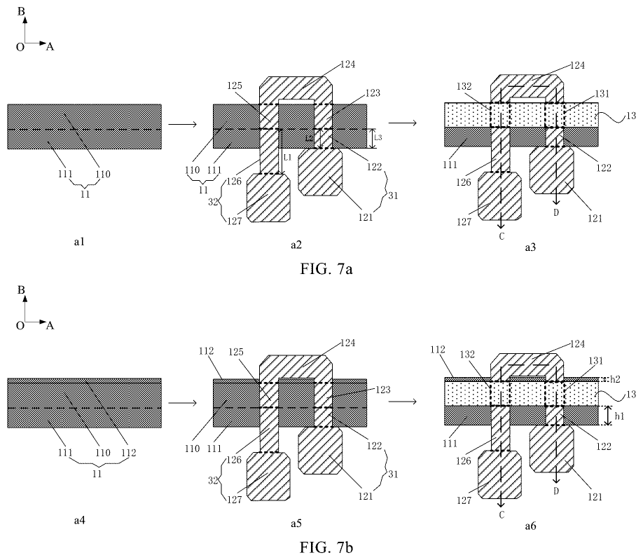

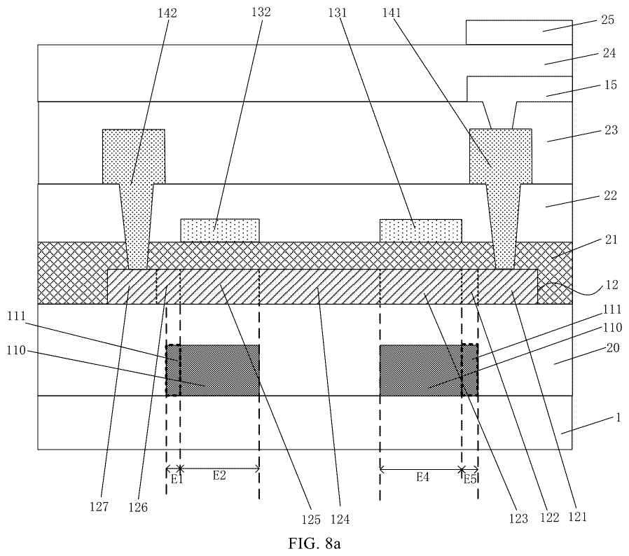

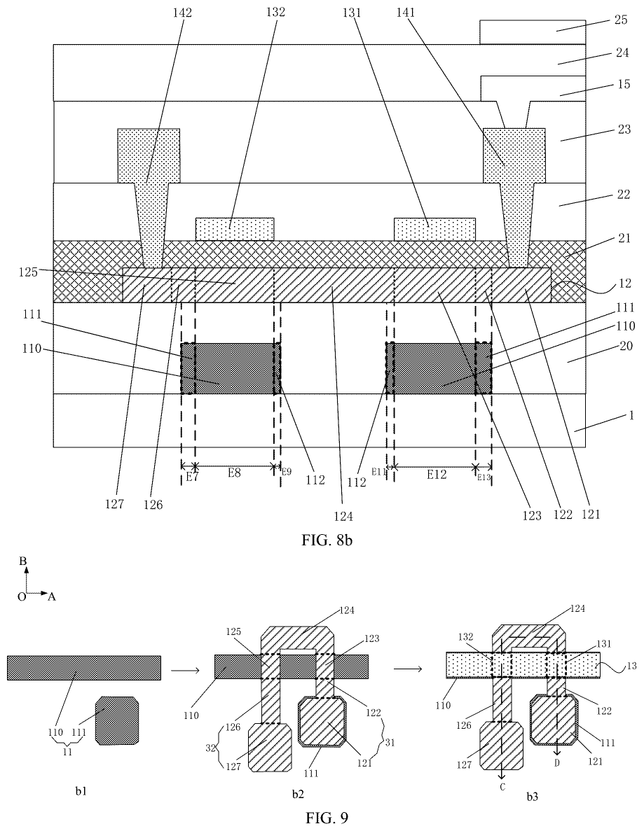

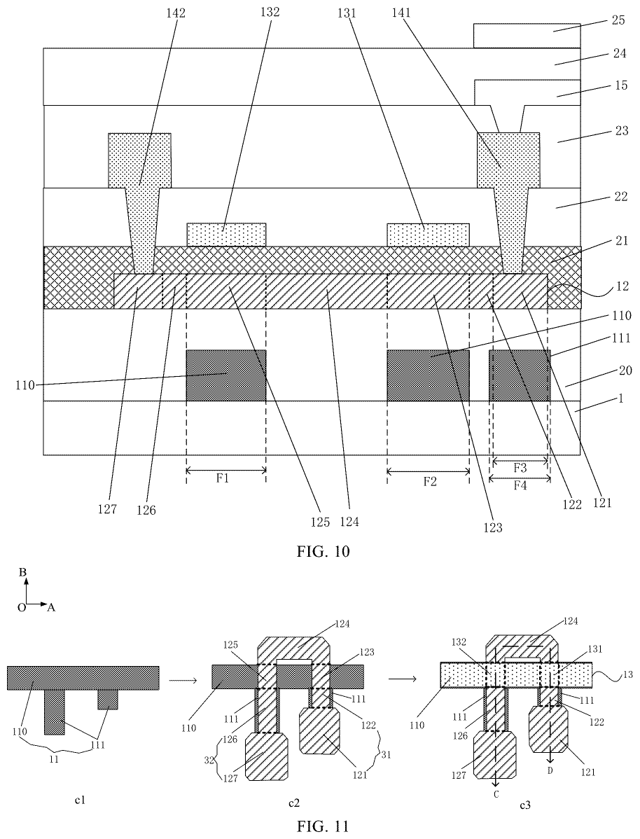

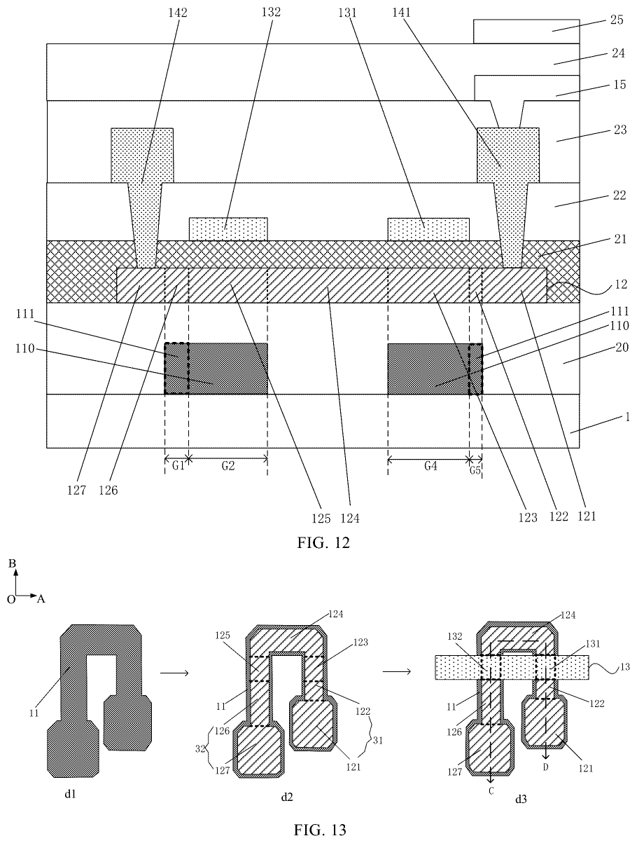

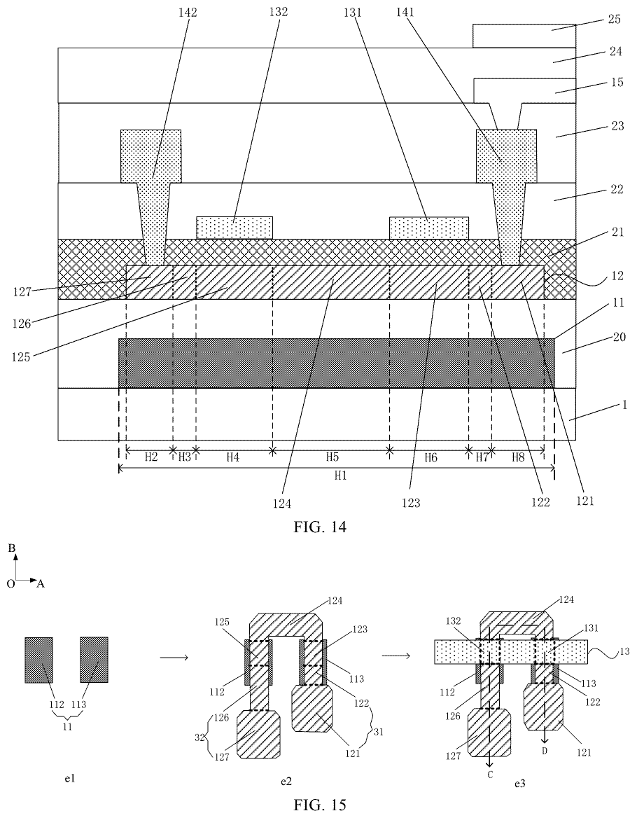

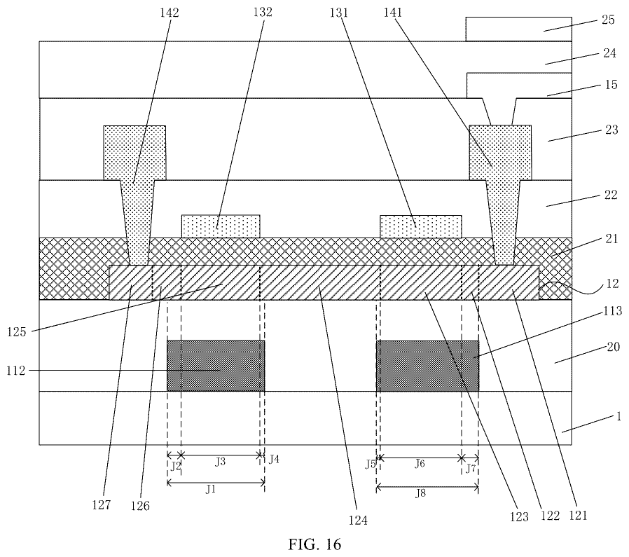

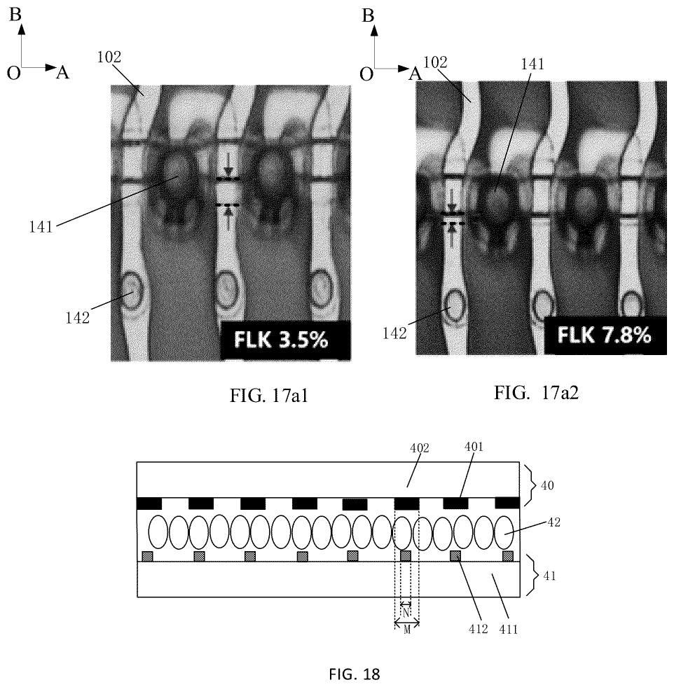

Based on the above, an embodiment of the present application provides an array base plate. Referring to FIG. 6a, the array base plate includes a substrate 1 and a plurality of sub-pixels 2 that are disposed on the substrate 1 and are arranged in an array. Each of the sub-pixels includes a light shielding layer, a semiconductor layer, a grid layer, a source-drain layer and a pixel electrode layer that are arranged in layer configuration on the substrate sequentially.

Referring to FIG. a2 in FIG. 7a, the semiconductor layer includes a first contacting part 31, a first channel part 123, a doping part 124, a second channel part 125 and a second contacting part 32 that are sequentially connected. Referring to FIG. a3 in FIG. 7a, the grid layer includes a first grid electrode 131 and a second grid electrode 132. Referring to FIG. 8a, the source-drain layer includes a first electrode 141 and a second electrode 142, the pixel electrode layer includes a pixel electrode 15, the first electrode 141 is electrically connected to the first contacting part and the pixel electrode 15, and the second electrode is electrically connected to the second contacting part. (FIG. 8a illustrates by taking the case as an example in which the first electrode 141 is electrically connected to a first contacting sub-part 121 of the first contacting part and the second electrode 142 is electrically connected to a second contacting sub-part 127 of the second contacting part.)

Referring to FIG. 8a, the first channel part 123 and the first grid electrode 131 intersect or overlap in the direction perpendicular to the substrate 1, and the second channel part 125 and the second grid electrode 132 intersect or overlap in the direction perpendicular to the substrate 1. The orthographic projection of the light shielding layer on the substrate at least covers the orthographic projections on the substrate of the first channel part, the second channel part and a part of the first contacting part. (FIG. 8a illustrates by taking the case as an example in which the orthographic projection of the light shielding layer 11 on the substrate 1 at least covers the orthographic projections on the substrate 1 of the first channel part 123, the second channel part 125 and the first doping sub-part 122 of the first contacting part.)

The material of the light shielding layer may be a light-tight metal material, such as molybdenum, aluminum and an aluminum-neodymium alloy. The shape of the light shielding layer is not limited, and may be particularly determined according to the semiconductor layer and the grid layer. The orthographic projection of the light shielding layer on the substrate refers to the orthographic projection of the light shielding layer on the substrate in the direction perpendicular to the substrate. The orthographic projections of the other film layers on the substrate are similar to that, and will not be explained below.

The orthographic projection of the light shielding layer on the substrate may cover a part of the orthographic projection of the first contacting part on the substrate, and may also cover the whole of the orthographic projection of the first contacting part on the substrate. Certainly, the light shielding layer may also cover the orthographic projections on the substrate of the components such as the second contacting part and the doping part.

In the semiconductor layer, the overall shape of the first contacting part, the first channel part, the doping part, the second channel part and the second contacting part that are sequentially connected is not limited. As an example, the overall shape may be a straight strip shape, a U shape and so on. Considering the saving of the room, a U shape may be employed. The semiconductor layer may be an N-type semiconductor layer.

Referring to FIGS. 6a and 6b, the array base plate may further include a plurality of grid lines 101 and a plurality of data lines 102 that intersect with each other, the grid lines 101 are electrically connected to the first grid electrodes G1 and the second grid electrodes G2 of each row of the sub-pixels 2, and the data lines 102 are electrically connected to the second electrodes C2 of each row of the sub-pixels 105. In each of the sub-pixels, the first electrode C1 is electrically connected to the pixel electrode 103. The data lines may be arranged in the same layer as the first electrodes and the second electrodes, and the data lines are connected to the second electrodes. Alternatively, the second electrodes are the parts of the data lines that intersect or overlap with the second contacting parts in the direction perpendicular to the substrate.

Certainly, in each of the sub-pixels, in order to prevent mutual influence between two neighboring layers, referring to FIG. 8a, a first insulating layer 20 may be disposed between the light shielding layer and the semiconductor layer. A grid insulating layer 21 may be disposed between the semiconductor layer and the grid layer. An inter-layer-medium layer 22 may be disposed between the grid layer and the source-drain layer, the first electrode 141 may be electrically connected to the first contacting part by a first via hole extending throughout the inter-layer-medium layer 22 and the grid insulating layer 21, and the second electrode 142 may be electrically connected to the second contacting part by a second via hole extending throughout the inter-layer-medium layer 22 and the grid insulating layer 21. A second insulating layer 23 may be disposed between the source-drain layer and the pixel electrode layer, and the pixel electrode 15 may be electrically connected to the first electrode 141 by a via hole extending throughout the second insulating layer 23. A common electrode layer may be disposed on the side of the pixel electrode layer that is further from the source-drain layer, the common electrode layer may include a common electrode 25, and the common electrode 25 and the pixel electrode 15 may form an electric field therebetween, to drive the liquid crystal to deflect. Certainly, the array base plate may further include other film layers and components, merely the film layers and the components that are relevant to the inventiveness are described herein, and the other components may be obtained from the related art, and are not discussed herein further.

The array base plate may be applied to liquid-crystal display panels such as the TN (Twisted Nematic) type, the VA (Vertical Alignment) type, the IPS (In-Plane Switching) type or the ADS (Advanced Super Dimension Switch) type, and any products or components having a displaying function that include those liquid-crystal display panels, such as a television set, a digital camera, a mobile phone and a tablet personal computer.

The transistor formed by the semiconductor layer, the grid layer and the source-drain layer is a top-grid-bigrid-type transistor, and the bigrid-type transistor may be a LTPS (Low Temperature Poly-silicon) type transistor, an oxide-type transistor or an amorphous-silicon-type transistor, which is not limited herein. In large-size high-PPI products, the LTPS-type transistor is mostly used. The leakage current of the bigrid-type transistor is less than the leakage current of a single-grid-type transistor.

According to the characteristics of transistors, transistors may be classified into N-type transistors and P-type transistors. An N-type transistor will be taken as an example below for the description. The N-type transistor may include a grid electrode, a source electrode and a drain electrode, wherein the source electrode and the drain electrode may be exchanged. In the N-type transistor, the terminal of the low level is referred to as the source electrode, and the terminal of the high level is referred to as the drain electrode, wherein the electric current flows from the drain electrode to the source electrode. When the N-type transistor is applied to a display panel, in positive-frame displaying (i.e., driving by using the positive-polarity data signal Vdata⁺ shown in FIG. 5), the side of the pixel electrode is in the low potential, the electrode of the transistor electrically connected to the pixel electrode is the source electrode, the side of the data line is in the high potential, and the electrode of the transistor electrically connected to the data line is the drain electrode. In negative-frame displaying (i.e., driving by using the negative-polarity data signal Vdata⁻ shown in FIG. 5), the side of the pixel electrode is in the high potential, the electrode of the transistor electrically connected to the pixel electrode is the drain electrode, the side of the data line is in the low potential, and the electrode of the transistor electrically connected to the data line is the source electrode. In other words, when driven by using data signals of different polarities, the source electrode and the drain electrode of the N-type transistor change. In the N-type transistor, the positive-frame leakage current is greater than the negative-frame leakage current, and the cut-off region in the transfer characteristic curve has a serious “tail warping” (which indicates that the positive-frame leakage current is serious).

Regarding the first electrode and the second electrode, the first electrode is electrically connected to the first contacting part and the pixel electrode, and the second electrode may be electrically connected to the second contacting part and the data line. Regarding an N-type transistor, when it is driven by using a positive-polarity data voltage, the first electrode may be referred to as the source electrode, and the second electrode may be referred to as the drain electrode. The principle of the reduction of the leakage current according to the present application will be described below: In the positive-frame maintaining stage of the transistor, if the depletion region at the edge of the channel is illuminated, then the region can be excited to generate hole-electron pairs, and some of the electrons, after obtaining a certain energy (for example, an energy greater than 2 eV), can transit to the edge of the conduction band. Those high-energy charge carriers can easily diffuse without being restricted by the potential energy, and move in the direction of the electric field formed with the bias voltage (grid voltage). The holes flow toward the channel, while the electrons flow toward the drain side, whereby the high electric field between the source electrode and the drain electrode is mainly concentrated at the drain side. If the quantity of the electrons moving from the source side to the drain side can be reduced, then the magnitude of the leakage current can be reduced. Therefore, in the present application, a light shielding layer is provided, wherein the orthographic projection of the light shielding layer on the substrate at least covers a first channel part, a second channel part and a part of a first contacting part: in other words, the light shielding layer at least blocks the first channel part, the second channel part and a part of the first contacting part. Accordingly, when the array base plate is applied to a liquid-crystal display panel, the light shielding layer can block the light rays emitted by the backlight source to the first channel part, the second channel part and a part of the first contacting part, which can reduce the quantity of the hole-electron pairs generated by the excitation by the illumination from the first contacting part, thereby reducing the quantity of the electrons that move to the second contacting part in the positive-frame maintaining stage, in turn reducing the illumination leakage current, and ameliorating the problem of flicker caused by the leakage current.

Optionally, in order to increase the aperture ratio to the largest extent, referring to FIG. a2 and FIG. a3 in FIG. 7a, the grid layer further includes a grid line 13, the first grid electrode 131 is the part of the grid line 13 that intersects or overlaps with the first channel part 13 in the direction perpendicular to the substrate, and the second grid electrode 132 is the part of the grid line 13 that intersects or overlaps with the second channel part 125 in the direction perpendicular to the substrate.

Referring to FIG. a2 and FIG. a3 in FIG. 7a, the grid line 13 extends in a first direction (the direction OA), the orthographic projection of the doping part 124 on the substrate is located on a first side of the orthographic projection of the grid line 13 on the substrate, and the orthographic projections of the first contacting part 31 and the second contacting part 32 on the substrate are located on a second side of the orthographic projection of the grid line 13 on the substrate, wherein the first side and the second side are opposite.

The doping part, the first contacting part, the second contacting part, the first channel part and the second channel part may form the U shape shown in FIG. a2 in FIG. 7a. The first direction is not particularly limited, and may be the direction OA shown in FIG. 7a.

In one or more embodiments, referring to FIG. a3 in FIG. 7a. FIG. b3 in FIG. 9 and FIG. c3 in FIG. 11, the light shielding layer extends in the first direction (the direction OA), and the orthographic projection of the grid line 13 on the substrate is located within the orthographic projection of the light shielding layer on the substrate.

In an aspect, that can simplify the process, to reduce the time quantity of the patterning processes. In another aspect, because grid lines are mostly made from a metal, and metals can reflect light rays, the light rays emitted by the backlight source to the grid line might be reflected to the semiconductor layer, which in turn increases the magnitude of the leakage current. In order to prevent that the orthographic projection of the grid line on the substrate is located within the orthographic projection of the light shielding layer on the substrate, and accordingly the light shielding layer can block the grid line, and prevent the light rays of the backlight source from being emitted to the grid line, to further reduce the magnitude of the leakage current.

Further optionally, in order to facilitate the fabrication, referring to FIGS. 7a. 9 and 11, the light shielding layer 11 at least includes an overlapping part 110 and a first part 111, the overlapping part 110 extends in the first direction (the direction OA), the orthographic projection of the overlapping part on the substrate coincides with the orthographic projection of the grid line on the substrate, and the orthographic projection of the first part 111 on the substrate is located on the second side of the orthographic projection of the grid line 13 on the substrate.

Referring to FIGS. 7a. 9 and 11, the first contacting part 31 includes a first contacting sub-part 121 and a first doping sub-part 122, and the first doping sub-part 122 is disposed between the first contacting sub-part 121 and the first channel part 123. Referring to FIGS. 8a. 10 and 12, the first contacting sub-part 121 is electrically connected to the first electrode 141.

The orthographic projection of the first doping sub-part on the substrate is located within the orthographic projection of the first part on the substrate: and/or, the orthographic projection of the first contacting sub-part on the substrate is located within the orthographic projection of the first part on the substrate.

In the first contacting part, the ion doping concentration of the first contacting sub-part is greater than the ion doping concentration of the first doping sub-part. The first contacting sub-part is a heavily doped region, and is used to electrically connect the first electrode. The first doping sub-part is a lightly doped region (LDD region). The ion doping concentration of the doping part may be equal to the ion doping concentration of the first doping sub-part.

That the light shielding layer at least includes an overlapping part and a first part refers to that the light shielding layer includes an overlapping part and a first part. In this case, the overlapping part can block the light rays emitted by the backlight source to the grid line, and the first part can block the light rays emitted by the backlight source to the first doping sub-part and/or the first contacting sub-part. Alternatively, the light shielding layer may further include the part other than the overlapping part and the first part, for example, the second part 112 shown in FIG. 7b, the orthographic projection of the second part on the substrate is located on the first side of the orthographic projection of the grid line on the substrate, and the orthographic projections of the second part and the doping part on the substrate partially intersect or overlap. In this case, the second part can block part of the light rays emitted by the backlight source to the doping part.

That the orthographic projection of the first doping sub-part on the substrate is located within the orthographic projection of the first part on the substrate: and/or, the orthographic projection of the first contacting sub-part on the substrate is located within the orthographic projection of the first part on the substrate includes three cases:

In the first case, referring to FIGS. 7a. 7b and 11, the orthographic projection of the first doping sub-part 122 on the substrate is located within the orthographic projection of the first part 111 on the substrate.

Accordingly, the first part can block the light rays emitted by the backlight source to the first doping sub-part. Because the first doping sub-part is closer to the first channel part, under the excitation by the illumination, hole-electron pairs are very easily generated. The blocking by the first part can block the light rays emitted by the backlight source to the first doping sub-part, thereby highly reducing the quantity of the hole-electron pairs generated by the excitation by the illumination, in turn reducing the quantity of the electrons that move to the second contacting part in the positive-frame maintaining stage, and finally reducing the illumination leakage current.

In this case, the first part may block the first contacting sub-part, or may not block the first contacting sub-part, which is not limited herein.

In the second case, referring to FIG. 9, the orthographic projection of the first contacting sub-part 121 on the substrate is located within the orthographic projection of the first part 111 on the substrate.

Accordingly, the first part can block the light rays emitted by the backlight source to the first contacting sub-part. Because the first contacting sub-part can also generate the hole-electron pairs under the excitation by the illumination, the blocking by the first part can block the light rays emitted by the backlight source to the first contacting sub-part, thereby highly reducing the quantity of the hole-electron pairs generated by the excitation by the illumination, in turn reducing the quantity of the electrons that move to the second contacting part in the positive-frame maintaining stage, and finally reducing the illumination leakage current.

In this case, the first part may block the first doping sub-part, or may not block the first doping sub-part, which is not limited herein.

In the third case, both of the orthographic projections of the first doping sub-part and the first contacting sub-part on the substrate are located within the orthographic projection of the first part on the substrate.

Accordingly, the first part can block both of the first doping sub-part and the first contacting sub-part at a same time, and can block the light rays emitted by the backlight source to the first doping sub-part and the first contacting sub-part, thereby highly reducing the quantity of the hole-electron pairs generated by the excitation by the illumination, in turn reducing the quantity of the electrons that move to the second contacting part in the positive-frame maintaining stage, and finally reducing the illumination leakage current.

The orthographic projection of the second contacting part on the substrate may be located within the orthographic projection of the first part on the substrate, or, the orthographic projection of the second contacting part on the substrate and the orthographic projection of the first part on the substrate do not intersect or overlap, which is not limited herein, and is required to be selected according to practical design conditions.

Different structures will be provided further below according to the cases of the blocking of the second contacting part.

In the first case, the second contacting part is not blocked.

Optionally, referring to FIG. 9, the orthographic projection of the second contacting part 127 on the substrate and the orthographic projection of the first part 111 on the substrate do not intersect or overlap, and the orthographic projection of the doping part 124 on the substrate and the orthographic projection of the light shielding layer 11 on the substrate do not intersect or overlap.

Accordingly, the light shielding layer does not block the second contacting part and the doping part, which can reduce the area of the light shielding layer, thereby facilitating to save the room.

Further optionally, when the orthographic projection of the first contacting sub-part on the substrate is located within the orthographic projection of the first part on the substrate, and the orthographic projection of the first doping sub-part on the substrate and the orthographic projection of the first part on the substrate do not intersect or overlap, the first part and the overlapping part are not connected. The structure of the light shielding layer may be shown in FIG, a in FIG. 9, and includes the first part 111 and the overlapping part 110 that are not connected. In such a structure, referring to FIGS. 9 and 10, the first part 111 blocks the first contacting sub-part 121, the overlapping part 110 blocks the grid line 13, the first channel part 123 and the second channel part 125, and the doping part 124, the second contacting part 32 and the first doping sub-part 122 are not blocked. Referring to FIG. 10, the orthographic projection of the second channel part 125 on the substrate 1 and a part of the orthographic projection F1 of the overlapping part 110 on the substrate 1 coincide, the orthographic projection of the first channel part 123 on the substrate 1 and a part of the orthographic projection F2 of the overlapping part 110 on the substrate 1 coincide, and the orthographic projection F3 of the first contacting sub-part 121 on the substrate 1 is located within the orthographic projection F4 of the first part 111 on the substrate 1.

In the second case, a part of the second contacting part is blocked.

Optionally, referring to FIGS. 7a. 7b and 11, the second contacting part 32 includes a second contacting sub-part 127 and a second doping sub-part 126, and the second doping sub-part 126 is disposed between the second contacting sub-part 127 and the second channel part 125. Referring to FIGS. 8a. 8b and 12, the second contacting sub-part 127 is electrically connected to the second electrode 142. At least part of the orthographic projection of the second doping sub-part 126 on the substrate 1 is located within the orthographic projection of the first part 111 on the substrate 1.

In the second contacting part, the ion doping concentration of the second contacting sub-part is greater than the ion doping concentration of the second doping sub-part. The second contacting sub-part is a heavily doped region, and is used to electrically connect the second electrode. The second doping sub-part is a lightly doped region (LDD region). The ion doping concentrations of the second doping sub-part, the doping part and the first doping sub-part may be equal.

That at least part of the orthographic projection of the second doping sub-part on the substrate is located within the orthographic projection of the first part on the substrate includes: Referring to FIGS. 7a and 8a, a part of the orthographic projection of the second doping sub-part 126 on the substrate 1 is located within the orthographic projection of the first part 111 on the substrate 1. Alternatively, referring to FIGS. 11 and 12, the whole of the orthographic projection of the second doping sub-part 126 on the substrate 1 is located within the orthographic projection of the first part 111 on the substrate 1.

At least part of the orthographic projection of the second contacting sub-part on the substrate may be located within the orthographic projection of the first part on the substrate: in other words, the first part can block at least part of the second contacting sub-part. Alternatively, referring to FIGS. 8a. 8b and 12, the orthographic projection of the second contacting sub-part 127 on the substrate 1 does not intersect or overlap with the orthographic projection of the first part 111 on the substrate 1; in other words, the second contacting sub-part is not blocked, which is not limited herein.

The first part can block at least part of the light rays emitted by the backlight source to the second doping sub-part, thereby reducing the quantity of the hole-electron pairs generated by the excitation by the illumination from the second doping sub-part, in turn reducing the quantity of the electrons at the position where the second doping sub-part is located, and further reducing the illumination leakage current.

Further optionally, the orthographic projection of the second contacting sub-part on the substrate and the orthographic projection of the first part on the substrate do not intersect or overlap. In other words, the first part does not block the second contacting sub-part, which can reduce the design area of the first part.

In order to simplify the structure and facilitate the implementation, when the orthographic projection of the first doping sub-part on the substrate is located within the orthographic projection of the first part on the substrate, and the orthographic projection of the first contacting sub-part on the substrate and the orthographic projection of the first part on the substrate do not intersect or overlap, referring to FIGS. 7a. 7b and 11, the first part 111 extends in the first direction (the direction OA), and is connected to the overlapping part 110.

Further optionally, referring to FIG. a2 in FIG. 7a, the length L1 of the second doping sub-part 126 in the second direction (the direction OB) is greater than the length L2 of the first doping sub-part 122 in the second direction (the direction OB). Accordingly, the second contacting sub-part 127 and first contacting sub-part 121 are arranged in stagger in the second direction (the direction OB), which can further save the room.

Referring to FIG. a2 in FIG. 7a, the width L3 of the first part 111 in the second direction (the direction OB) is equal to the length L2 of the first doping sub-part 122 in the second direction (the direction OB), wherein the second direction (the direction OB) is perpendicular to the first direction (the direction OA). Referring to FIG. 8a, the orthographic projection of the doping part 124 on the substrate 1 and the orthographic projection of the light shielding layer 11 on the substrate 1 do not intersect or overlap.

The light shielding layer 11 shown in FIG. 7a is of an asymmetrical structure: in other words, the configurations of the light shielding layer on the two sides of the grid line are asymmetrical. Particularly, the first part 111 of the light shielding layer 11 is disposed at a region corresponding to the second side of the grid line 13, the overlapping part 110 is disposed at a region corresponding to the grid line 13, and the region corresponding to the first side of the grid line is not provided with the light shielding layer. Referring to FIG. 8a, the orthographic projection of the second channel part 125 on the substrate 1 and a part of the orthographic projection E2 of the overlapping part 110 on the substrate 1 coincide, the orthographic projection of the first channel part 123 on the substrate 1 and a part of the orthographic projection E4 of the overlapping part 110 on the substrate 1 coincide, the orthographic projection of the first doping sub-part 122 on the substrate 1 is within the orthographic projection of the first part 111 on the substrate 1, and a part of the orthographic projection of the second doping sub-part 126 on the substrate 1 is within the orthographic projection of the first part 111 on the substrate 1. In FIG. 8a. E1 and E5 are individually part of the orthographic projection of the first part 111 on the substrate 1.

As limited by the fabrication precision, optionally, referring to FIG. 7b, the light shielding layer further includes a second part 112, and the orthographic projection of the second part 112 on the substrate is located on the first side of the orthographic projection of the grid line 13 on the substrate. In other words, the second part 112 of the light shielding layer 11 is disposed at the region corresponding to the first side of the grid line 13, and the second part 112 can block a part of the doping part 124.

Referring to FIG. 8b, the orthographic projection E9 of the second part 112 on the substrate 1 and the orthographic projection of the doping part 124 on the substrate 1 partially intersect or overlap. Referring to FIG. a6 in FIG. 7b, the width h2 of the second part 112 in the second direction (the direction OB) is less than the width h1 of the first part 111 in the second direction (the direction OB).

The second part may, as shown in FIG. 7b, extend in the first direction (the direction OA), and be connected to the overlapping part 110. The light shielding layer shown in FIG. 7b is of an asymmetrical structure: in other words, the configurations of the light shielding layer on the two sides of the grid line are asymmetrical. Particularly, referring to FIG. a6 in FIG. 7b, the first part 111 of the light shielding layer 11 is disposed at a region corresponding to the second side of the grid line 13, the overlapping part 110 is disposed at a region corresponding to the grid line 13, the second part 112 is disposed at the region corresponding to the first side of the grid line 13, and the width h2 of the second part 112 in the second direction (the direction OB) is less than the width h1 of the first part 111 in the second direction (the direction OB). Referring to FIG. 8b, the orthographic projection of the second channel part 125 on the substrate 1 and a part of the orthographic projection E8 of the overlapping part 110 on the substrate 1 coincide, the orthographic projection of the first channel part 123 on the substrate 1 and a part of the orthographic projection E12 of the overlapping part 110 on the substrate 1 coincide, the orthographic projection of the first doping sub-part 122 on the substrate 1 is located within the orthographic projection of the first part 111 on the substrate 1, a part of the orthographic projection of the doping part 124 on the substrate 1 is within the orthographic projections E9 and E11 of the second part 112 on the substrate 1, part of the orthographic projection of the second doping sub-part 126 on the substrate 1 is located within the orthographic projection E7 of the first part 111 on the substrate 1, and the orthographic projection of the first doping sub-part 122 on the substrate 1 is located within the orthographic projection of the first part 111 on the substrate 1. In FIGS. 8b, E7 and E13 are individually part of the orthographic projection of the first part 111 on the substrate 1.

The light shielding layer shown in FIG. 7a is an ultimate design of an asymmetrical structure; in other words, no second part is disposed. The difference between the width of the first part in the second direction and the width of the second part in the second direction is not limited herein. As an example, the difference between the width of the first part in the second direction and the width of the second part in the second direction may be 2 micrometers. Certainly, if the difference is higher, the effect of the improvement is better.

It should be noted that the above-described asymmetrical light shielding layer can reduce the leakage current excellently. Based on the same type of transistors, by detecting the flicker values and the leakage currents of transistors having the first part and the second part of different widths, table 1 and Table 2 can be obtained.

TABLE 1

| NO. | FLK | LS | Gate | Up | Down |
|---|---|---|---|---|---|
| #1 | 3.5% | 5.36 | 2.80 | 0.90 | 1.74 |
| #2 | 4.1% | 5.24 | 2.89 | 1.09 | 1.31 |
| #3 | 4.6% | 5.27 | 3.28 | 0.93 | 1.27 |
| #4 | 4.6% | 5.27 | 3.30 | 0.92 | 1.38 |
| #5 | 4.6% | 4.94 | 3.16 | 1.03 | 1.18 |
| #6 | 4.1% | 5.23 | 2.93 | 0.73 | 1.62 |
| #7 | 3.5% | 5.14 | 2.99 | 0.71 | 1.53 |
| #8 | 3.2% | 5.16 | 2.92 | 0.84 | 1.54 |
| #9 | 3.3% | 5.17 | 2.96 | 0.36 | 1.83 |
| #10 | 3.4% | 5.21 | 2.90 | 0.77 | 1.53 |
| #11 | 3.5% | 5.10 | 2.87 | 0.94 | 1.40 |
| #12 | 7.1% | 5.39 | 3.08 | 1.35 | 1.00 |
| #13 | 8.1% | 5.22 | 2.85 | 1.32 | 1.04 |
| #14 | 8.8% | 4.95 | 2.75 | 1.33 | 0.89 |
| #15 | 9.1% | 5.18 | 2.86 | 1.54 | 0.80 |
| #16 | 9.9% | 5.06 | 2.88 | 1.36 | 0.88 |
| #17 | 9.0% | 5.22 | 2.99 | 1.54 | 0.63 |
| #18 | 10.8% | 5.12 | 2.95 | 1.35 | 0.86 |
| #19 | 9.4% | 4.98 | 3.14 | 1.65 | 0.08 |
| #20 | 8.9% | 4.87 | 2.89 | 1.24 | 0.85 |

In Table 1, the first column represents different samples (totally 20 samples), FLK in the secondary column represents the flicker values, LS represents the width of the light shielding layer in the second direction, Gate represents the width of the grid line in the second direction, Up represents the width of the second part of the light shielding layer in the second direction, and Down represents the width of the first part of the light shielding layer in the second direction. It can be obtained from Table 1 that, in the samples 1-11, all of the Up values are less than the Down values, and all of the corresponding flicker values are less than 5%, which is far less than the industrial regulation requirement 10%. However, in the samples 12-20, all of the Up values are greater than the Down values, and all of the corresponding flicker values are greater than 7%. It is obtained by verification on the practical products that the above-described asymmetrical light shielding layer can effectively ameliorate the problem of flicker, especially by using the configuration in which the width of the second part of the light shielding layer in the second direction is less than the width of the first part in the second direction. FIG. 17a1 and FIG. 17a2 show two electron microscope diagrams, wherein the distance between the dotted lines is the width of the first part of the light shielding layer in the second direction (the direction OA). The width of the first part of the light shielding layer in the second direction in FIG. a1 is greater than the width of the first part of the light shielding layer in the second direction in FIG. a2. The FLK value of FIG. 17a1 is 3.5%, and the FLK value of FIG. 17a2 is 7.8%. FIG. 17a1 and FIG. 17a2 contain two transistors and three data lines 102, wherein the regions where the small circles in the data lines are located are the second electrodes 142, and the regions where the large circles between two data lines 102 are located are the first electrodes 141.

TABLE 2

| NO. | LS | GATE | UP | DOWN | IOFF@20000 nit |
|---|---|---|---|---|---|
| 1 | 4.37 | 1.98 | 0.71 | 1.68 | 1.11E−12 |
| 2 | 4.25 | 2.26 | 0.71 | 1.28 | 1.45E−12 |
| 3 | 4.14 | 2.22 | 0.72 | 1.20 | 1.18E−12 |
| 4 | 5.06 | 2.20 | 0.96 | 1.90 | 1.17E−12 |
| 5 | 4.46 | 2.48 | 0.64 | 1.34 | 1.11E−12 |
| 6 | 4.06 | 2.28 | 0.00 | 1.78 | 1.05E−12 |
| 7 | 4.47 | 2.43 | 0.79 | 1.25 | 1.15E−12 |
| AVE | 4.40 | 2.26 | 0.65 | 1.49 | 1.17E−12 |
| 1 | 4.52 | 2.39 | 1.29 | 0.84 | 1.23E−12 |
| 2 | 4.46 | 2.39 | 1.29 | 0.78 | 1.20E−12 |
| 3 | 4.28 | 1.89 | 1.56 | 0.83 | 1.37E−12 |
| | 4.28 | 2.38 | 1.08 | 0.82 | 2.02E−12 |
| 5 | 4.38 | 2.42 | 1.15 | 0.81 | 1.79E−12 |
| 6 | 4.29 | 2.14 | 1.33 | 0.82 | 1.62E−12 |
| 7 | 3.96 | 2.20 | 1.01 | 0.75 | 1.32E−12 |
| 8 | 4.38 | 2.39 | 1.11 | 0.88 | 1.26E−12 |
| AVE | 4.32 | 2.28 | 1.23 | 0.82 | 1.48E−12 |

In Table 2, the first column represents different samples (the two groups include totally 15 samples), LS represents the width of the light shielding layer in the second direction, Gate represents the width of the grid line in the second direction, Up represents the width of the second part of the light shielding layer in the second direction, Down represents the width of the first part of the light shielding layer in the second direction, and IOFF@20000 nit represents the leakage current under the irradiation by the light rays of the brightness of 20000 nit. It can be obtained from Table 2 that the average value of the leakage currents of the 8 samples of the second group is greater than the average value of the leakage currents of the 7 samples of the first group by 25%. In the first group, all of the Up values of the 7 samples are less than the Down values. In the second group, all of the Up values of the 8 samples are greater than the Down values. It is obtained by verification on the practical products that the above-described asymmetrical light shielding layer can reduce the leakage current effectively, especially by using the configuration in which the width of the second part of the light shielding layer in the second direction is less than the width of the first part in the second direction.

Another structure of the light shielding layer will be further provided below.

Optionally, when the orthographic projection of the first doping sub-part on the substrate and the orthographic projection of the second doping sub-part on the substrate are located within the orthographic projection of the first part on the substrate, and the orthographic projections on the substrate of the first contacting sub-part, the second contacting sub-part and the doping part do not intersect or overlap with the orthographic projection of the first part on the substrate, the first part includes a first sub-part and a second sub-part, both of the first sub-part and the second sub-part are connected to the overlapping part, the orthographic projection of the first doping sub-part on the substrate is located within the orthographic projection of the first sub-part on the substrate, and the orthographic projection of the second doping sub-part on the substrate is located within the orthographic projection of the second sub-part on the substrate.

Accordingly, the first sub-part of the light shielding layer can block the light rays emitted by the backlight source to the first doping sub-part, the second sub-part can block the light rays emitted by the backlight source to the second doping sub-part, and the overlapping part can block the light rays emitted to the grid line, the first channel part and the second channel part. In such a structure, the first part has a low area, which facilitates to realize a high-PPI product.

In one or more embodiments, the orthographic projection of the semiconductor layer on the substrate is located within the orthographic projection of the light shielding layer on the substrate, and a shape of a boundary of the orthographic projection of the light shielding layer on the substrate and a shape of a boundary of the orthographic projection of the semiconductor layer on the substrate are the same. Referring to FIGS. 13 and 14, in the semiconductor layer, the orthographic projections on the substrate 1 of the first contacting sub-part 121, the first doping sub-part 122, the first channel part 123, the doping part 124, the second channel part 125, the second doping sub-part 126 and the second contacting sub-part 127 are H8, H7, H6, H5, H4, H3 and H2 respectively, all of which are located within the orthographic projection H1 of the light shielding layer 11 on the substrate 1.

Accordingly, the light shielding layer can block the light rays emitted by the backlight source to the semiconductor layer, and can block the light rays emitted by the backlight source to the first grid electrode and the second grid electrode at the same time. In such a structure, the light shielding layer is not required to block the whole grid line, thereby having a low design area.

In one or more embodiments, in order to reduce the area of the light shielding layer to the largest extent, referring to FIGS. 15 and 16, the light shielding layer 11 includes a first light shielding part 113 and a second light shielding part 112 that are not connected, the orthographic projection of the first light shielding part 113 on the substrate 1 at least covers the orthographic projection of the first grid electrode 131 on the substrate 1 and a part of the orthographic projection of the first contacting part 31 on the substrate 1, and the orthographic projection of the second light shielding part 112 on the substrate 1 at least covers the orthographic projection of the second grid electrode 132 on the substrate 1 and a part of the orthographic projection of the second contacting part 32 on the substrate 1.

That the orthographic projection of the first light shielding part on the substrate at least covers the orthographic projection of the first grid electrode on the substrate and a part of the orthographic projection of the first contacting part on the substrate includes: the orthographic projection of the first light shielding part on the substrate covers the orthographic projection of the first grid electrode on the substrate and a part of the orthographic projection of the first contacting part on the substrate. As an example, if the first contacting part includes the first contacting sub-part and the first doping sub-part, the orthographic projection of the first light shielding part on the substrate may cover at least part of the orthographic projection on the substrate of the first contacting sub-part or the first doping sub-part, and FIG. 15 illustrates by taking the case as an example in which the orthographic projection of the first light shielding part 113 on the substrate covers the orthographic projection of the first doping sub-part 122 on the substrate. Alternatively, the orthographic projection of the first light shielding part on the substrate covers the orthographic projection of the first grid electrode on the substrate and the whole of the orthographic projection of the first contacting part on the substrate. Alternatively, the orthographic projection of the first light shielding part on the substrate may also cover the orthographic projection other than the orthographic projections of the first grid electrode and the first contacting part on the substrate.

That the orthographic projection of the second light shielding part on the substrate at least covers the orthographic projection of the second grid electrode on the substrate and a part of the orthographic projection of the second contacting part on the substrate includes: the orthographic projection of the second light shielding part on the substrate covers the orthographic projection of the second grid electrode on the substrate and a part of the orthographic projection of the second contacting part on the substrate. As an example, if the second contacting part includes the second contacting sub-part and the second doping sub-part, the orthographic projection of the second light shielding part on the substrate may cover at least part of the orthographic projection on the substrate of the second contacting sub-part or the second doping sub-part, and FIG. 15 illustrates by taking the case as an example in which the orthographic projection of the second light shielding part 32 on the substrate covers a part of the orthographic projection of the second doping sub-part 126 on the substrate. Alternatively, the orthographic projection of the second light shielding part on the substrate covers the orthographic projection of the second grid electrode on the substrate and the whole of the orthographic projection of the second contacting part on the substrate. Alternatively, the orthographic projection of the second light shielding part on the substrate may also cover the orthographic projection other than the orthographic projections of the second grid electrode and the second contacting part on the substrate. In FIG. 16, the orthographic projection J6 of the first channel part 123 on the substrate 1, the orthographic projection J7 of the first doping sub-part 122 on the substrate 1 and a part of the orthographic projection J5 of the doping part 124 on the substrate 1 are located within the orthographic projection J8 of the first light shielding part 113 on the substrate 1, and the orthographic projection J3 of the second channel part 125 on the substrate 1, a part of the orthographic projection J2 of the second doping sub-part 126 on the substrate 1 and a part of the orthographic projection J4 of the doping part 124 on the substrate 1 are located within the orthographic projection J1 of the second light shielding part 112 on the substrate 1.

The length of the second doping sub-part in the second direction may be greater than the length of the first doping sub-part in the second direction, and the width in the first direction of the part of the second light shielding part that blocks the second doping sub-part is equal to the length of the first doping sub-part in the second direction. Accordingly, the second contacting sub-part and the first contacting sub-part are arranged in stagger in the second direction, which can further save the room, and, while ensuring reducing the leakage current, further reduce the area of the light shielding layer.

An embodiment of the present application further provides a display panel. Referring to FIG. 18, the display panel includes a color-film base plate 40 and the array base plate 41 stated above that face each other. The color-film base plate 40 includes a black matrix 401, and the orthographic projection M of the black matrix 401 on the substrate 411 of the array base plate 41 covers the orthographic projection N of the light shielding layer 412 of the array base plate 41 on the substrate 411.

It should be noted that the region of the array base plate that corresponds to the black matrix is a non-opening region. Disposing the light shielding layer within the non-opening region can, while not reducing the aperture ratio, reduce the leakage current and ameliorate flicker phenomenon, to improve the product quality and the user experience. In FIG. 18, the color-film base plate 40 may further include a bottom matrix 402, wherein the black matrix 401 may be disposed on the bottom matrix 402, and, certainly, may further include other components such as a color-film layer. The display panel may further include a liquid crystal 42 disposed between the color-film base plate 40 and the array base plate 41, to form a liquid-crystal display panel.

The type of the display panel is not limited, and it may be liquid-crystal display panels such as the TN (Twisted Nematic) type, the VA (Vertical Alignment) type, the IPS (In-Plane Switching) type or the ADS (Advanced Super Dimension Switch) type, and any products or components having a displaying function that include those liquid-crystal display panels, such as a television set, a digital camera, a mobile phone and a tablet personal computer.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. An array base plate, wherein the array base plate comprises a substrate and a plurality of sub-pixels that are disposed on the substrate and are arranged in an array;
each of the sub-pixels comprises a light shielding layer, a semiconductor layer, a grid layer, a source-drain layer and a pixel electrode layer that are arranged in layer configuration on the substrate sequentially;
the semiconductor layer comprises a first contacting part, a first channel part, a doping part, a second channel part and a second contacting part that are sequentially connected;
the grid layer comprises a first grid electrode and a second grid electrode;
the source-drain layer comprises a first electrode and a second electrode;
the pixel electrode layer comprises a pixel electrode;
the first electrode is electrically connected to the first contacting part and the pixel electrode, and the second electrode is electrically connected to the second contacting part;
the first channel part and the first grid electrode intersect or overlap in a direction perpendicular to the substrate, and the second channel part and the second grid electrode intersect or overlap in the direction perpendicular to the substrate; and
an orthographic projection of the light shielding layer on the substrate at least covers orthographic projections on the substrate of the first channel part, the second channel part and a part of the first contacting part.

2. The array base plate according to claim 1, wherein the grid layer further comprises a grid line;
the first grid electrode is a part of the grid line that intersects or overlaps with the first channel part in the direction perpendicular to the substrate, and the second grid electrode is a part of the grid line that intersects or overlaps with the second channel part in the direction perpendicular to the substrate; and
the grid line extends in a first direction, an orthographic projection of the doping part on the substrate is located on a first side of an orthographic projection of the grid line on the substrate, and orthographic projections of the first contacting part and the second contacting part on the substrate are located on a second side of the orthographic projection of the grid line on the substrate, wherein the first side and the second side are opposite.

3. The array base plate according to claim 2, wherein the light shielding layer extends in the first direction, and the orthographic projection of the grid line on the substrate is located within the orthographic projection of the light shielding layer on the substrate.

4. The array base plate according to claim 3, wherein the light shielding layer at least comprises an overlapping part and a first part, the overlapping part extends in the first direction, an orthographic projection of the overlapping part on the substrate coincides with the orthographic projection of the grid line on the substrate, and an orthographic projection of the first part on the substrate is located on the second side of the orthographic projection of the grid line on the substrate;
the first contacting part comprises a first contacting sub-part and a first doping sub-part, the first doping sub-part is disposed between the first contacting sub-part and the first channel part, and the first contacting sub-part is electrically connected to the first electrode; and
an orthographic projection of the first doping sub-part on the substrate is located within the orthographic projection of the first part on the substrate; and/or, an orthographic projection of the first contacting sub-part on the substrate is located within the orthographic projection of the first part on the substrate.

5. The array base plate according to claim 4, wherein the orthographic projection of the second contacting part on the substrate and the orthographic projection of the first part on the substrate do not intersect or overlap, and the orthographic projection of the doping part on the substrate and the orthographic projection of the light shielding layer on the substrate do not intersect or overlap.

6. The array base plate according to claim 5, wherein when the orthographic projection of the first contacting sub-part on the substrate is located within the orthographic projection of the first part on the substrate, and when the orthographic projection of the first doping sub-part on the substrate and the orthographic projection of the first part on the substrate do not intersect or overlap, the first part and the overlapping part are not connected.

7. The array base plate according to claim 4, wherein the second contacting part comprises a second contacting sub-part and a second doping sub-part, the second doping sub-part is disposed between the second contacting sub-part and the second channel part, and the second contacting sub-part is electrically connected to the second electrode; and
at least part of an orthographic projection of the second doping sub-part on the substrate is located within the orthographic projection of the first part on the substrate.

8. The array base plate according to claim 7, wherein an orthographic projection of the second contacting sub-part on the substrate and the orthographic projection of the first part on the substrate do not intersect or overlap.

9. The array base plate according to claim 8, wherein when the orthographic projection of the first doping sub-part on the substrate is located within the orthographic projection of the first part on the substrate, and the orthographic projection of the first contacting sub-part on the substrate and the orthographic projection of the first part on the substrate do not intersect or overlap, the first part extends in the first direction, and is connected to the overlapping part.

10. The array base plate according to claim 9, wherein a length of the second doping sub-part in a second direction is greater than a length of the first doping sub-part in the second direction;
a width of the first part in the second direction is equal to the length of the first doping sub-part in the second direction, wherein the second direction is perpendicular to the first direction; and
the orthographic projection of the doping part on the substrate and the orthographic projection of the light shielding layer on the substrate do not intersect or overlap.

11. The array base plate according to claim 9, wherein the light shielding layer further comprises a second part, and an orthographic projection of the second part on the substrate is located on the first side of the orthographic projection of the grid line on the substrate; and
the orthographic projection of the second part on the substrate and the orthographic projection of the doping part on the substrate partially intersect or overlap, and a width of the second part in a second direction is less than a width of the first part in the second direction.

12. The array base plate according to claim 8, wherein when the orthographic projection of the first doping sub-part on the substrate and the orthographic projection of the second doping sub-part on the substrate are located within the orthographic projection of the first part on the substrate, and when the orthographic projections on the substrate of the first contacting sub-part, the second contacting sub-part and the doping part do not intersect or overlap with the orthographic projection of the first part on the substrate, the first part comprises a first sub-part and a second sub-part, both of the first sub-part and the second sub-part are connected to the overlapping part, the orthographic projection of the first doping sub-part on the substrate is located within an orthographic projection of the first sub-part on the substrate, and the orthographic projection of the second doping sub-part on the substrate is located within an orthographic projection of the second sub-part on the substrate.

13. The array base plate according to claim 2, wherein an orthographic projection of the semiconductor layer on the substrate is located within the orthographic projection of the light shielding layer on the substrate, and a shape of a boundary of the orthographic projection of the light shielding layer on the substrate and a shape of a boundary of the orthographic projection of the semiconductor layer on the substrate are the same.

14. The array base plate according to claim 2, wherein the light shielding layer comprises a first light shielding part and a second light shielding part that are not connected, an orthographic projection of the first light shielding part on the substrate at least covers an orthographic projection of the first grid electrode on the substrate and a part of an orthographic projection of the first contacting part on the substrate, and an orthographic projection of the second light shielding part on the substrate at least covers an orthographic projection of the second grid electrode on the substrate and a part of the orthographic projection of the second contacting part on the substrate.

15. A display panel, wherein the display panel comprises a color-film base plate and the array base plate according to claim 1 that face each other; and
the color-film base plate comprises a black matrix, and an orthographic projection of the black matrix on the substrate of the array base plate covers the orthographic projection of the light shielding layer of the array base plate on the substrate.

16. The display panel according to claim 15, wherein the grid layer further comprises a grid line;
the first grid electrode is a part of the grid line that intersects or overlaps with the first channel part in the direction perpendicular to the substrate, and the second grid electrode is a part of the grid line that intersects or overlaps with the second channel part in the direction perpendicular to the substrate; and
the grid line extends in a first direction, an orthographic projection of the doping part on the substrate is located on a first side of an orthographic projection of the grid line on the substrate, and orthographic projections of the first contacting part and the second contacting part on the substrate are located on a second side of the orthographic projection of the grid line on the substrate, wherein the first side and the second side are opposite.

17. The display panel according to claim 16, wherein the light shielding layer extends in the first direction, and the orthographic projection of the grid line on the substrate is located within the orthographic projection of the light shielding layer on the substrate.

18. The display panel according to claim 17, wherein the light shielding layer at least comprises an overlapping part and a first part, the overlapping part extends in the first direction, an orthographic projection of the overlapping part on the substrate coincides with the orthographic projection of the grid line on the substrate, and an orthographic projection of the first part on the substrate is located on the second side of the orthographic projection of the grid line on the substrate;
the first contacting part comprises a first contacting sub-part and a first doping sub-part, the first doping sub-part is disposed between the first contacting sub-part and the first channel part, and the first contacting sub-part is electrically connected to the first electrode; and
an orthographic projection of the first doping sub-part on the substrate is located within the orthographic projection of the first part on the substrate; and/or, an orthographic projection of the first contacting sub-part on the substrate is located within the orthographic projection of the first part on the substrate.

19. The display panel according to claim 18, wherein the orthographic projection of the second contacting part on the substrate and the orthographic projection of the first part on the substrate do not intersect or overlap, and the orthographic projection of the doping part on the substrate and the orthographic projection of the light shielding layer on the substrate do not intersect or overlap.

20. The display panel according to claim 19, wherein when the orthographic projection of the first contacting sub-part on the substrate is located within the orthographic projection of the first part on the substrate, and when the orthographic projection of the first doping sub-part on the substrate and the orthographic projection of the first part on the substrate do not intersect or overlap, the first part and the overlapping part are not connected.
